(19) United States
(12) Patent Application Publication
(10) Pub. No.: US 2019/0067924 A1
(43) Pub. Date: Feb. 28, 2019

(54) ELECTRICAL JUNCTION BOX

(71) Applicant: Sumitomo Wiring Systems, Ltd., Yokkaichi, Mie (JP)

(72) Inventor: Junya Aichi, Yokkaichi, Mie (JP)

(73) Assignees: Sumitomo Wiring Systems, Ltd., Yokkaichi, Mie (JP); Sumitomo Wiring Systems, Ltd., Yokkaichi, Mie (JP)

(21) Appl. No.: 15/767,272

(22) PCT Filed: Aug. 8, 2016
(86) PCT No.: PCT/JP2016/073256

§ 371 Date: Apr. 10, 2018

(30) Foreign Application Priority Data
Oct. 26, 2015 (JP) 2015-209818

(51) Int. Cl. H02G 3/08; H05K 5/02

(52) U.S. Cl. CPC H02G 3/088; H05K 5/0217; H02G 3/081

(57) ABSTRACT

An electrical junction box includes a circuit assembly, a first case that includes an upper wall and is provided with an accommodating portion for accommodating the circuit assembly, and a second case that is locked to the first case and covers the accommodating portion. A reservoir portion with a recessed shape capable of storing water infiltrating through a boundary between the first case and the second case is provided on the upper side of the upper wall of the accommodating portion, and the second case covers the upper side of the reservoir portion and is locked to the first case such that the distance of a gap between the upper edge of the reservoir portion and the inner surface of the second case is smaller than or equal to a predetermined distance.

### CROSS-REFERENCE TO RELATED APPLICATIONS

This application is the U.S. national stage of PCT/JP2016/073256 filed Aug. 8, 2016, which claims priority of Japanese Patent Application No. JP 2015-209818 filed Oct. 26, 2015.

### TECHNICAL FIELD

The technology disclosed in this specification relates to an electrical junction box.

### BACKGROUND

An electrical junction box to be mounted in an automobile or the like includes a circuit assembly, and a case inside which an accommodating portion for accommodating the circuit assembly is provided (see Japanese Patent No. 4304207 below, for example).

When water attaches to the case of such an electrical junction box, infiltrates the case, and reaches the inside of the accommodating portion, there is a concern that short circuits and other problems will arise in the circuit assembly.

To address this, Japanese Patent No. 4304207, for example, proposes a structure in which a drain that is continuous from the upper side (upper end) of the case to the lower end of the case via the lateral surface is formed, so that water that has infiltrated the case is drained without being allowed to reach the accommodating portion of the circuit assembly and is prevented from reaching the inside of the accommodating portion.

However, in the above-mentioned configuration, the measures taken against the infiltration of water into the case are not sufficient. Therefore, there has been demand for suppressing the infiltration of water into the case. In this regard, it is conceivable that a route through which water infiltrates the case is sealed using a sealing member, but this is not practical because an increase in the number of components or the like leads to an increase in cost.

The technology disclosed in this specification was accomplished based on the above-mentioned circumstances, and it is an object thereof to provide an electrical junction box in which the infiltration of water into the case is suppressed with a simple configuration.

### SUMMARY

An electrical junction box disclosed in this specification includes a circuit assembly, a first case that includes an upper wall and is provided with an accommodating portion for accommodating the circuit assembly, and a second case that is locked to the first case and covers the accommodating portion, wherein a reservoir portion with a recessed shape for storing water infiltrating through a boundary between the first case and the second case is provided on an upper side of the upper wall of the accommodating portion, and the second case covers an upper side of the reservoir portion and is locked to the first case such that a distance of a gap between an upper edge of the reservoir portion and an inner surface of the second case is smaller than or equal to a predetermined distance.

With the above-mentioned configuration, if a small amount of water infiltrates through the boundary between the first case and the second case, the water is stored in the reservoir portion located outside the accommodating portion, thus making it possible to suppress the infiltration of water into the accommodating portion. Regarding the above-mentioned configuration, in a case where a predetermined distance that defines a gap between the upper edge of the reservoir portion and the inner surface of the second case is set to be smaller than or equal to the threshold protruding height of water stored in the reservoir portion, for example, when the amount of water infiltrating through the boundary between the first case and the second case increases and the reservoir portion is thus filled with water, the water with which the reservoir portion is filled comes into contact with the inner surface of the second case, leading to a state in which the first case and the second case stick to each other due to surface tension (Laplace force), and the infiltration of water into the case is suppressed. It should be noted that the “threshold protruding height” as used herein refers to a maximum height of the water surface from the upper edge of the lateral surface of the reservoir portion with a recessed shape during a process in which a water surface protrudes over the upper edge of the reservoir portion and then water overflows when water is poured into the reservoir portion.

The electrical junction box disclosed in this specification may also have a configuration in which a plurality of the reservoir portions are lined up along an edge of the second case on the upper side of the upper wall of the first case.

With the above-mentioned configuration, when water infiltrates from a specific portion of the edge of the second case, the infiltrating water is stored in a reservoir portion facing that portion. When the water with which the reservoir portion is filled comes into contact with the inner surface of the second case, the first case and the second case stick to each other at this portion, and the infiltration of water is thus suppressed. As described above, in the case where water continuously infiltrates from a specific portion, the infiltration of water into the case can be quickly suppressed when a reservoir portion with a relatively small capacity that faces the portion is filled.

The electrical junction box disclosed in this specification may also have a configuration in which the first case includes a left wall and a right wall that extend downward from two lateral edges of the upper wall, an upper drain channel extending to a lateral drain channel formed on at least one of the left wall and the right wall is provided at a position adjacent to the reservoir portion on a side opposite to the edge of the second case on the upper side of the upper wall of the first case, and a drain outlet is provided that connects the lateral drain channel and an outside of the second case in a state in which the second case is locked to the first case and through which water flowing on the lateral channel is drained outward from the second case.

With the above-mentioned configuration, even when water overflows from the reservoir portion, the water can be smoothly drained outward from the electrical junction box through the upper drain channel, the lateral drain channel, and the drain outlet.

The electrical junction box disclosed in this specification may also have a configuration in which an inclined surface that is inclined downward toward the upper drain channel is formed at an upper edge of a lateral wall on the upper drain channel side of the reservoir portion.

With the above-mentioned configuration, water overflowing from the reservoir portion can be reliably introduced toward the drain channel.

### Advantageous Effects of Invention

With the present invention, an electrical junction box in which the infiltration of water into the case is suppressed with a simple configuration can be provided.

### BRIEF DESCRIPTION OF DRAWINGS

FIG. 1 is a perspective view of the exterior of an electrical junction box according to an embodiment.

FIG. 2 is a perspective view of the exterior of the electrical junction box, as viewed from another angle.

FIG. 3 is a perspective view of a first case.

FIG. 4 is a front view of the electrical junction box.

FIG. 5 is a right side view of the electrical junction box.

FIG. 6 is a cross-sectional view taken along line B-B in FIG. 5.

FIG. 7 is a cross-sectional view taken along line A-A in FIG. 4.

FIG. 8 is a front view of the first case.

FIG. 9 is a left side view of the first case.

FIG. 10 is a plan view (top view) of the first case.

FIG. 11 is a cross-sectional view taken along line F-F in FIG. 9.

FIG. 12 is a cross-sectional view taken along line E-E in FIG. 9.

FIG. 13 is a cross-sectional view taken along line C-C in FIG. 8.

FIG. 14 is a cross-sectional view taken along line D-D in FIG. 8.

FIG. 15 is a schematic diagram showing a state in which water with which a reservoir portion is filled is not in contact with the inner surface of a second case.

FIG. 16 is a schematic diagram showing a state in which water with which a reservoir portion is filled is in contact with the inner surface of the second case.

### DETAILED DESCRIPTION OF PREFERRED EMBODIMENTS

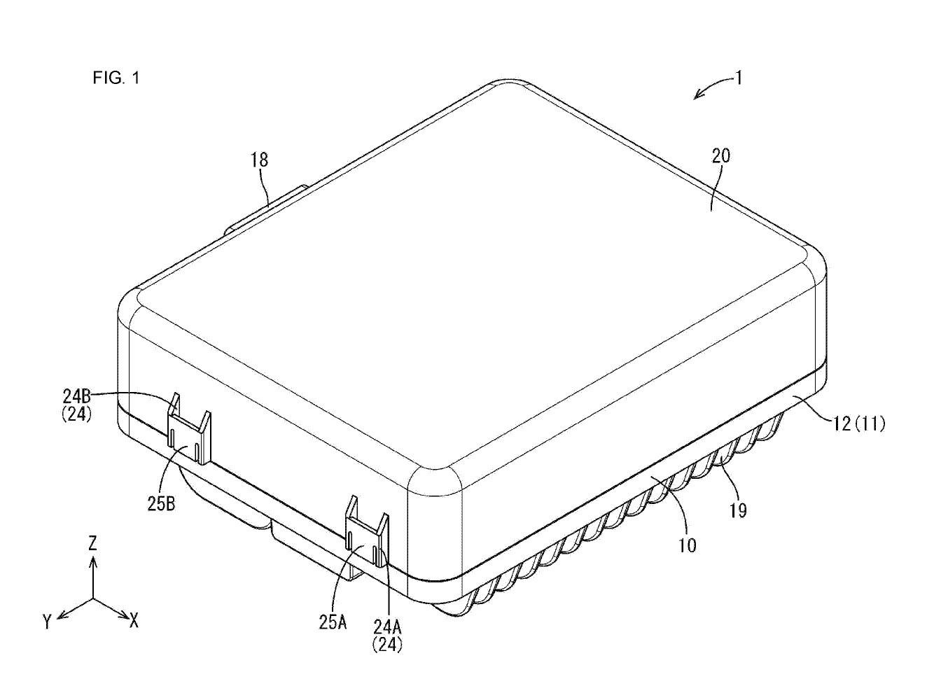

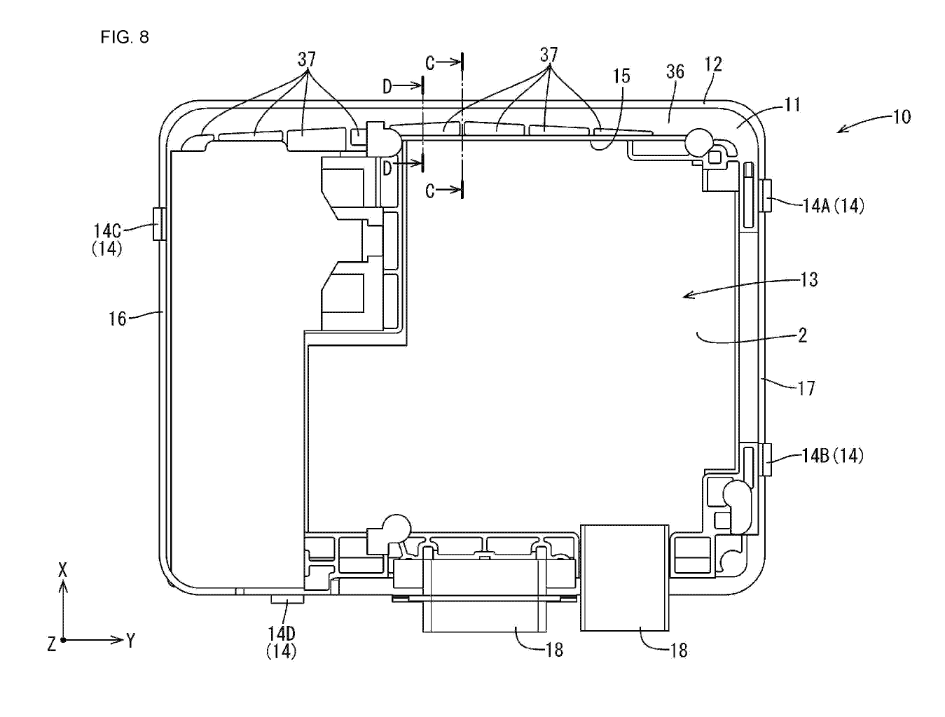

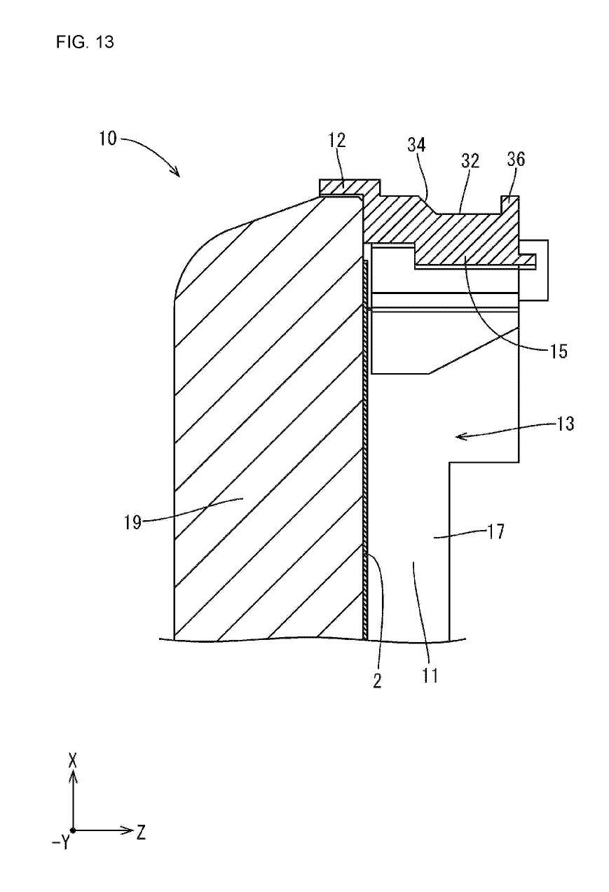

An embodiment of the present invention will be described with reference to FIGS. 1 to 16.

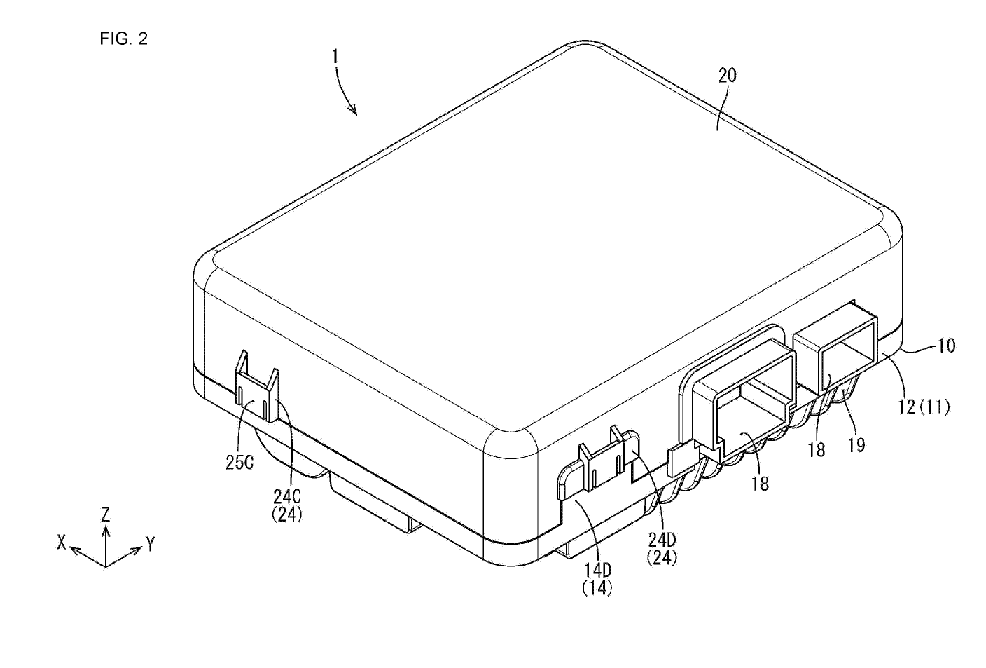

FIGS. 1 and 2 show the exterior of an electrical junction box 1 according to this embodiment. The electrical junction box 1 is arranged between a power supply (not shown) and in-vehicle electrical equipment (not shown) such as a lamp or a motor, and carries out switching of the in-vehicle electrical equipment, for example. The electrical junction box 1 is arranged such that in FIG. 1, the X direction indicates the bottom right front side (the −X direction indicates the top left rear side), the Y direction indicates the bottom left front side (the −Y direction indicates the top right rear side), and the Z direction indicates the top front side (the −Z direction indicates the bottom rear side). In the following description, the directions are indicated according to the above-mentioned arrangement directions, and directional lines are indicated in the drawings.

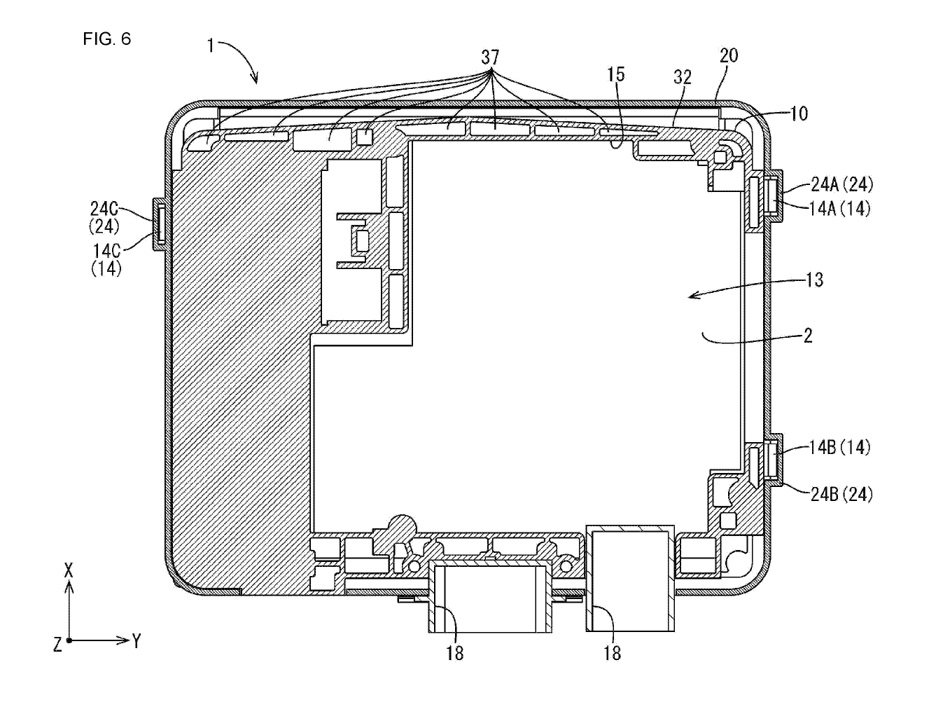

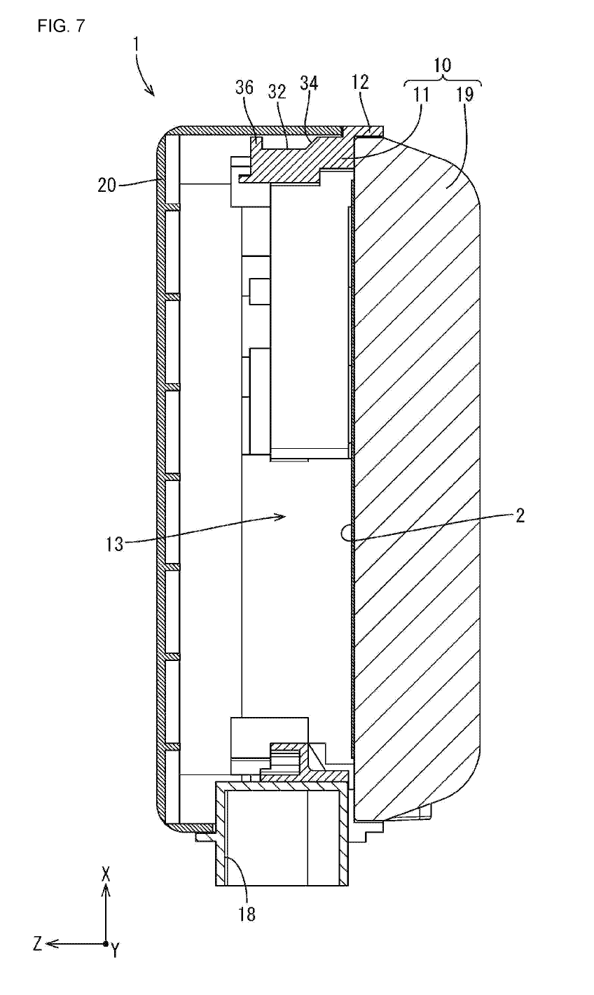

The electrical junction box 1 shown in FIGS. 1 and 2 includes a circuit board 2 (an example of a circuit assembly; see FIG. 7 for example), a first case 10 including an accommodating portion 13 (see FIG. 6 for example) for accommodating the circuit assembly 2, and a second case 20 made of an insulating resin that is locked to the outer surface of the first case 10.

An electrical conductive path (not shown) is formed on the circuit board 2 using a printed wiring technique, and various electronic components (not shown) are connected thereto.

As shown in FIG. 2 for example, two connector fitting portions 18 project from the lower side of the electrical junction box 1, and connectors (not shown) are fitted thereto and electrically connected to the circuit assembly 2.

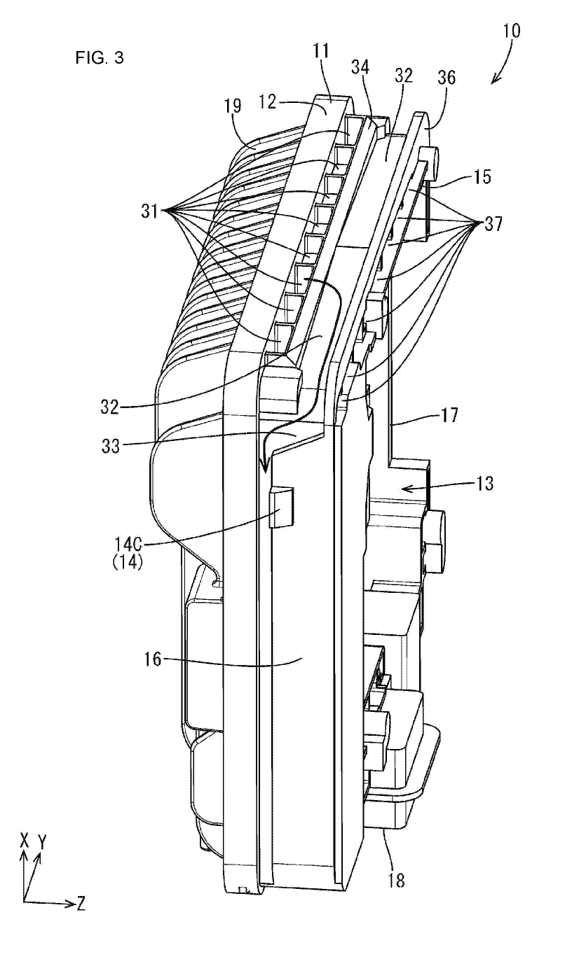

The first case 10 will be described with reference to mainly FIG. 3.

The first case 10 includes a frame 11 made of an insulating resin that has an outline with a substantially rectangular frame shape and is open toward the front side and the rear side, and a heat sink 19 made of metal that is attached to it, closing the opening on the rear side of the frame 11.

The accommodating portion 13 for accommodating the circuit board 2 in a vertical manner is provided on the front side of the heat sink 19 inside the frame 11. A frame edge portion 12 projects outward from the peripheral edge of the opening of the frame 11 to which the heat sink 19 is attached.

In the frame 11 of the first case 10, a plurality of reservoir portions 31 that are formed in a recessed shape and open upward, an inclined surface 34 that is inclined downward toward the front side, an upper drain channel 32 that is inclined downward toward the left side and the right side, and a flange 36 that projects upward are formed and lined up in this order from the frame edge portion 12 toward the front side on the upper side of an upper wall 15 covering the upper side of the circuit board 2 accommodated in the accommodating portion 13.

As shown also in FIGS. 6, 8, 10, 12, and 14, a plurality of hollow portions 37 are provided underneath the flange 36 and the upper drain channel 32. The frame 11 is thus prevented from warping and is reduced in weight.

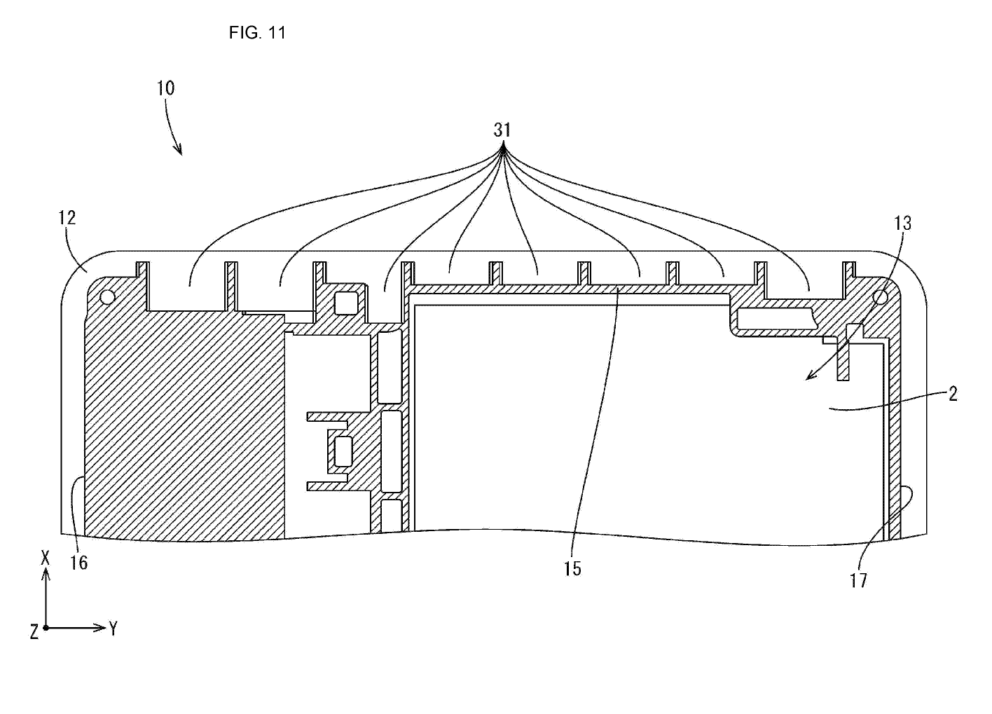

As shown also in FIG. 11 for example, the plurality of reservoir portions 31 are lined up along the front surface of the frame edge portion 12, and the rear surfaces of the reservoir portions 31 are continuous with the front surface of the frame edge portion 12. As shown in FIG. 7 for example, the second case 20 is locked to the first case 10 in a state in which the rear edge of the second case 20 is in contact with the front surface of the frame edge portion 12, and therefore, water infiltrating through between these boundary surfaces flows directly into the reservoir portions 31. The arrangement state of the reservoir portions 31 and the like will be described later in detail.

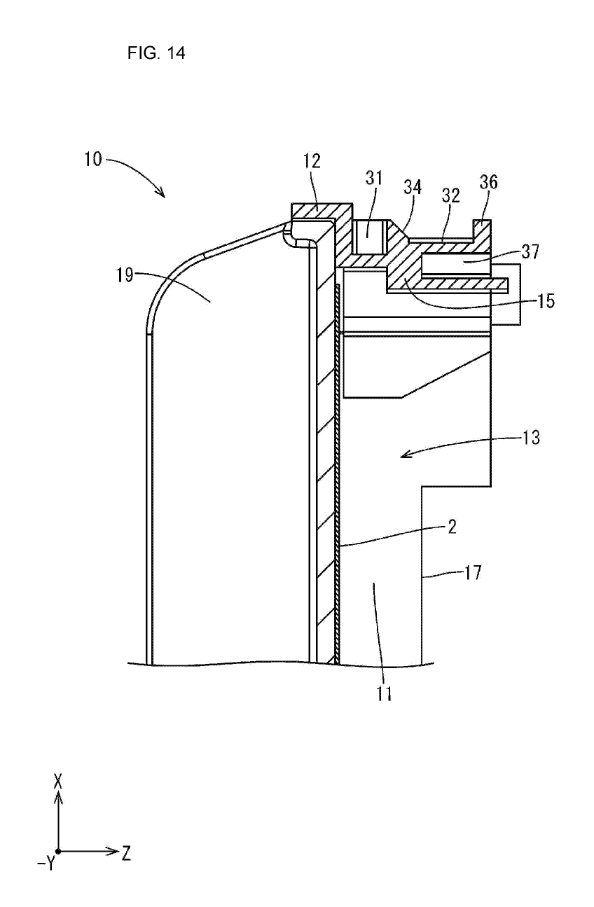

As shown also in FIG. 14 for example, the reservoir portions 31 are arranged on the rear side of the hollow portions 37. The reservoir portions 31 can contribute to the warping prevention and weight reduction of the frame 11 in the state in which no water is stored therein in the same manner as the hollow portions 37, and the inner space of the first case 10 is thus effectively used.

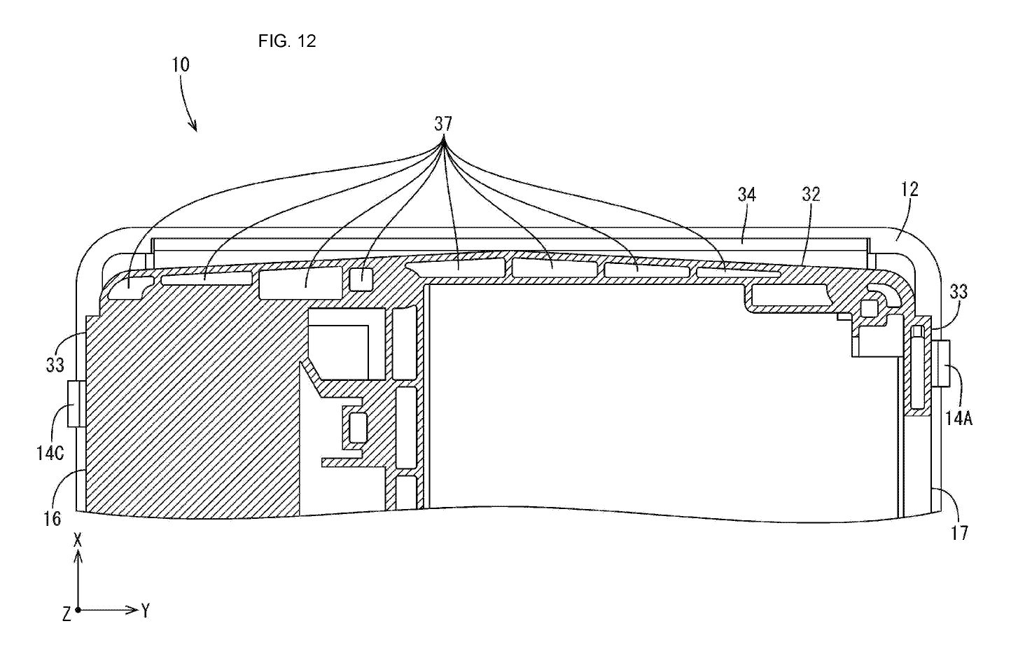

As shown also in FIGS. 7, 9, 13, and 14, the inclined surface 34 inclined downward toward the upper drain channel 32 is formed at the front upper edges of the reservoir portions 31. As shown also in FIGS. 6 and 12, the upper drain channel 32 is formed such that its central portion in the left-right direction is the highest and its height is lowered toward both of the left and right sides. As a result, water flowing in the upper drain channel 32 reliably runs down toward both of the left and right lateral surfaces along the inclination.

As shown also in FIGS. 6 and 12, the upper drain channel 32 is inclined downward toward the left and right sides from the highest central portion. As shown also in FIGS. 7, 9, 13, and 14, the flange 36 projects upward on the front side of the upper drain channel 32, and thus prevents water from reaching the opening on the front side of the accommodating portion 13. Water that overflows from the reservoir portions 31, runs down on the inclined surface 34 and reaches the upper drain channel 32 is blocked by the flange 36, and guided down toward the left and right sides along the inclination of the upper drain channel 32.

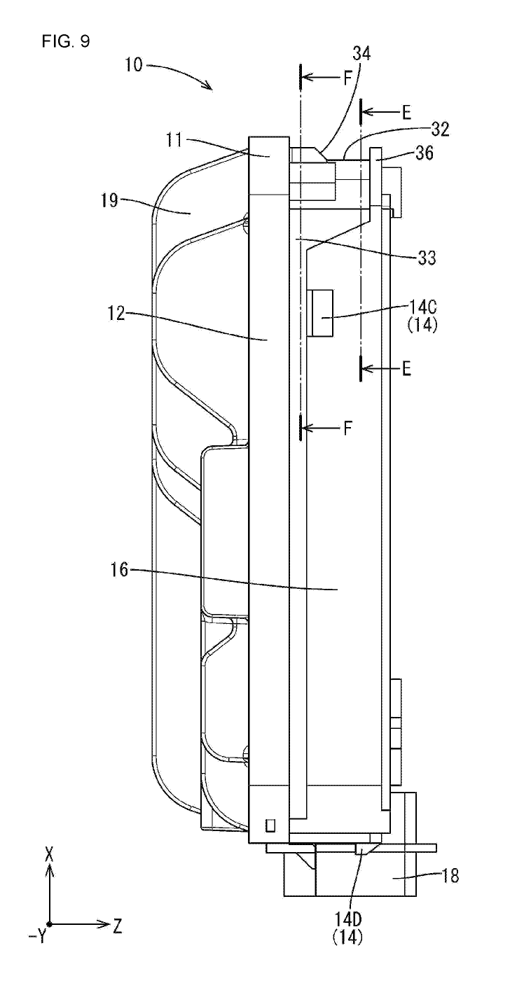

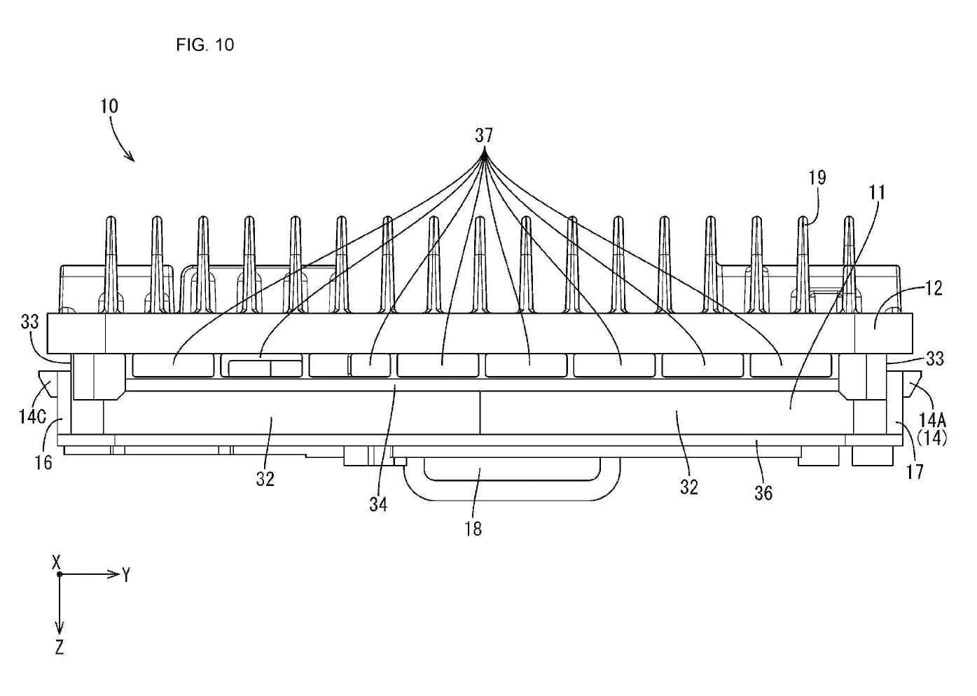

As shown also in FIGS. 9 and 10 for example, the left and right ends of the upper drain channel 32 are respectively continuous with lateral drain channels 33 provided on the outer surfaces of a left wall 16 and a right wall 17 of the first case. The lateral drain channels 33 extend along the frame edge portion 12, and their widths decrease toward the lower side due to the rear surface of the flange 36 protruding toward the rear side on the left wall 16 and the right wall 17 of the first case 10. A locking portion 14C projects from the left wall 16 of the first case 10, and locking portions 14A and 14B project from the right wall 17 of the first case 10, such that their rear surfaces are flush with the front edges of the lateral drain channels 33.

Next, the second case 20 will be described.

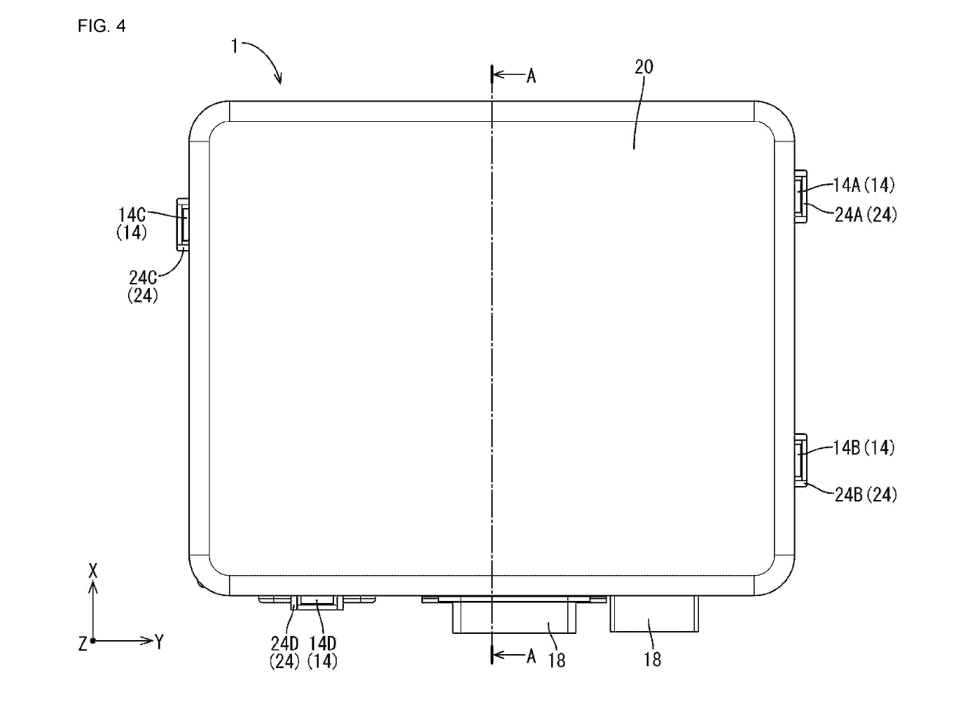

As shown in FIGS. 1 and 2, the second case 20 is formed in a box shape that is open toward the rear side, and provided with locked portions 24 (24A, 24B, 24C, 24D) including two locked portions formed on the right surface, one locked portion formed on the left surface, and one locked portion formed on the lower side. As shown in FIG. 4 for example, these locked portions 24 are locked to the locking portions 14 (14A, 14B, 14C, 14D) that are provided at corresponding positions on the outer surface of the frame 11 of the first case 10, and the second case 20 is thus locked and covers the accommodating portion 13 of the first case 10.

Next, the formation of drain outlets 35 involved in the attachment of the second case 20 to the first case 10 will be described.

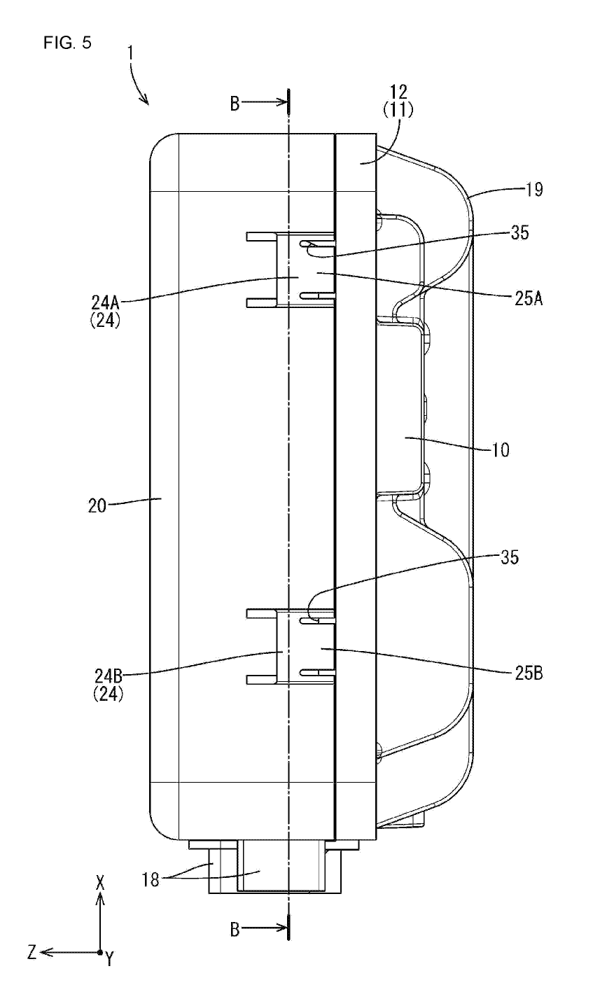

As shown in FIG. 5, in the state in which the locked portions 24 are locked to the locking portions 14, the drain outlets 35 are formed at those portions where the locked portion 24 is locked to the locking portion 14, but not at the portion where the locked portion 24D is locked to the locking portion 14D on the lower side of the electrical junction box 1.

As shown in FIGS. 1 and 2 for example, the locked portions 24A, 24B, and 24C of the second case 20 protrude outward from the left surface and the right surface of the second case 20, and include locked pieces 25A, 25B, and 25C that cover the locking portions 14A, 14B, and 14C projecting from the left wall 16 and the right wall 17 of the first case 10 from the outside when the locking portions 14A, 14B, and 14C are locked thereto. Claws (not shown) to be locked to the rear surfaces of the locking portions 14A, 14B, and 14C project from the inside of the locked pieces 25A, 25B, and 25C, slits are formed on the upper side and the lower side of each of the locked pieces 25A, 25B, and 25C, and the rear ends of the locked pieces 25A, 25B, and 25C are provided as free ends. Accordingly, when the second case 20 is press-fitted from the outside of the first case 10, the locked pieces 25A, 25B, and 25C are displaced outward due to the inner claws coming into contact with the locking portions 14A, 14B, and 14C. When the second case 20 is further pressed down and the claws pass over the locking portions 14A, 14B, and 14C, the locked pieces 25A, 25B, and 25C undergo elastic restoration, and the claws are locked to the rear surfaces of the locking portions 14A, 14B, and 14C. As a result, the locking portions 14 are prevented from dislodging from the locked portions 24, and the second case 20 is thus attached to the first case 10.

Here, the rear ends of the locked pieces 25A, 25B, and 25C between the slits are arranged to form gaps above the lateral drain channels 33 provided on the outer surfaces of the left wall 16 and the right wall 17 of the first case 10 in the state in which the locked portions 24A, 24B, and 24C are locked to the locking portions 14A, 14B, and 14C. As a result, the lateral drain channels 33 arranged on the rear side of the locking portions 14A, 14B, and 14C are in communication with the outside of the second case 20 inside the locked pieces 25A, 25B, and 25C, thus forming the drain outlets 35. Water flowing through the reservoir portions 31, the inclined surface 34, the upper drain channel 32, and the lateral drain channels 33 is drained to the outside of the second case 20 through these drain outlets 35.

In this embodiment, as shown in FIG. 3 for example, the lateral drain channels 33 extend over the entire lengths of the left wall 16 and the right wall 17, that is, they extend to the lower ends while facing the positions at which the locking portions 14A, 14B, and 14C are formed. Water that has not been drained through the drain outlets 35 runs down directly to the lower ends of the lateral drain channels 33, and drained downward through between the boundary surfaces of the first case 10 and the second case 20.

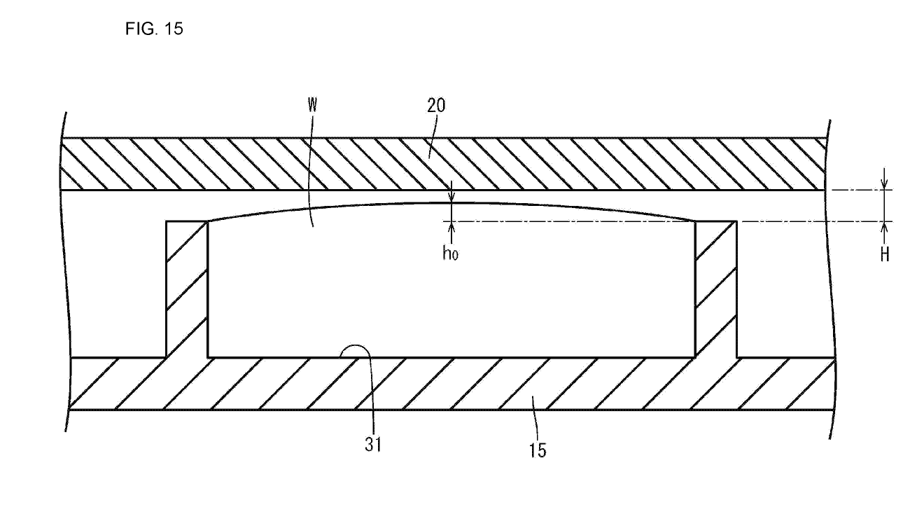

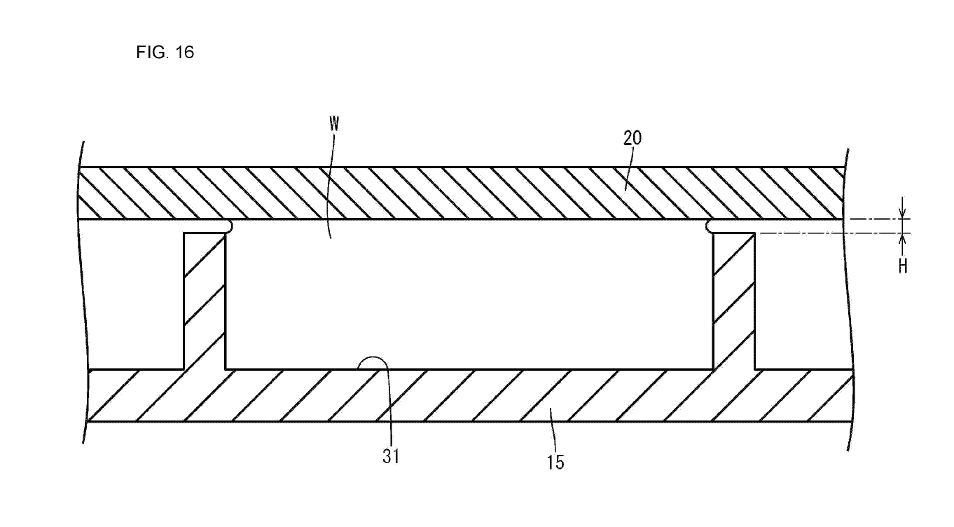

Next, the arrangement state of the second case 20 with respect to the reservoir portions 31 and the like will be described with reference to FIGS. 15 and 16, which schematically show the positional relationship between water W with which the reservoir portions 31 are filled, and the inner surface of the second case 20.

As shown in a portion of FIG. 15, the water W with which the reservoir portion 31 is filled protrudes from the upper edge of the reservoir portion 31 due to surface tension. When water is further poured thereinto, the water surface protrudes to a height that exceeds a certain height and collapses, and the water W thus overflows. A maximum height of the water surface from the upper edge of the lateral surface of the reservoir portion 31 during a process in which a water surface protrudes over the upper edge of the reservoir portion 31 and then water overflows when water is poured into the reservoir portion 31 is referred to as “threshold protruding height h₀”.

FIG. 15 shows a state in which a gap H between the upper edge of the reservoir portion 31 and the inner surface of the second case 20 is set to be larger than the threshold protruding height h₀ of the water W stored in the reservoir portion 31 for the comparison with the technology disclosed in this specification. In such an arrangement state, the water W with which the reservoir portion 31 is filled overflows without coming into contact with the inner surface of the second case 20, and flows into the upper drain channel 32 via the inclined surface 34.

In contrast, FIG. 16 shows a state in which the gap H between the upper edge of the reservoir portion 31 and the inner surface of the second case 20 is set to be smaller than the threshold protruding height h₀ of the water W stored in the reservoir portion 31. In such an arrangement state, the water W that is stored in the reservoir portion 31 and protrudes due to surface tension comes into contact with the inner surface of the second case 20. As shown in FIG. 16, Laplace force acting on the inside of the water W forming a meniscus acts to attach the second case 20 and the reservoir portion 31 to each other, and thus the second case 20 sticks to the first case 10. As a result, the infiltration of water through the boundary between the second case 20 and the first case 10 is prevented.

In the electrical junction box 1 according to this embodiment, a predetermined distance that defines a gap between the upper edge of the reservoir portion 31 and the inner surface of the second case 20 is set to the above-described threshold protruding height h₀. As a result, the reservoir portions 31 are arranged such that the water W with which the reservoir portions 31 are filled is allowed to come into contact with the inner surface of the second case 20 locked to the first case 10, that is, the situation shown in FIG. 16 can be realized.

Hereinafter, the functions of this embodiment will be described.

Water may attach to the upper surface of the electrical junction box 1 mounted in a vehicle during rainfall, car washing, and the like. When the attaching water infiltrates into the second case 20 through a small gap between the first case 10 and the second case 20, the water flows along the edge of the second case 20 into the reservoir portions 31 formed on the upper side of the upper wall 15 of the first case 10, and is then stored. When water further infiltrates and the reservoir portions 31 are thus filled with water, the water comes into contact with the inner surface of the second case 20, and thus the second case 20 sticks to the first case 10, resulting in the suppression of the infiltration of water.

Water that has overflowed from the reservoir portions 31 runs down on the inclined surface 34 and flows into the upper drain channel 32 provided to be adjacent to the reservoir portions 31 on the upper side of the upper wall 15. Water that has flowed into the upper channel 32 flows toward both sides along the inclination and reaches the lateral drain channels 33 provided on the left wall 16 and the right wall 17. Water that runs down on the lateral drain channel 33 is drained outward from the second case 20 through the drain outlets 35 formed inside the locked pieces 25A, 25B, and 25C at the portions where the locked portions 24A, 24B, and 24C are locked to the locking portions 14A, 14B, and 14C, or through between the boundary surfaces of the first case 10 and the second case 20 at the lower ends of the lateral drain channels 33.

Hereinafter, the effects of this embodiment will be described.

With this embodiment, if a small amount of water infiltrates through the boundary between the first case 10 and the second case 20, the water is stored in the reservoir portions 31 located outside the accommodating portion 13, thus making it possible to suppress the infiltration of water into the accommodating portion 13. When the amount of water infiltrating through the boundary between the first case 10 and the second case 20 increases, water with which the reservoir portions 31 are filled comes into contact with the inner surface of the second case 20, leading to a state in which the first case 10 and the second case 20 stick to each other due to surface tension (Laplace force), and the infiltration of water is suppressed.

With this embodiment, when water infiltrates from a specific portion of the edge of the second case 20, the infiltrating water is stored in the reservoir portion 31 facing the portion from which the water infiltrates, out of the plurality of reservoir portions 31 lined up on the upper side of the upper wall 15 of the first case 10. When the water with which the reservoir portion 31 is filled comes into contact with the inner surface of the second case 20, the first case 10 and the second case 20 stick to each other at this portion, and the infiltration of water is thus suppressed. As described above, the infiltration of water can be quickly suppressed when a reservoir portion 31 with a relatively small capacity that faces the portion from which water infiltrates is filled.

With this embodiment, even when water overflows from the reservoir portions 31, the water can be smoothly drained outward from the electrical junction box 1 through the upper drain channel 32, the lateral drain channels 33, the drain outlets 35, and the like. Here, water overflowing from the reservoir portions 31 can be reliably introduced toward the upper drain channel 32 using the inclined surface 34.

### OTHER EMBODIMENTS

The present invention is not limited to the embodiment that has been described above with reference to the drawings, and embodiments such as those described below are also included in the technical scope of the present invention.

Although the above-described embodiment has a configuration in which a gap smaller than the threshold protruding height of the water W stored in the reservoir portions 31 is formed between the upper edges of the reservoir portions 31 and the inner surface of the second case 20 in a locked state, a configuration in which the upper edges of the reservoir portions 31 are in intimate contact with the inner surface of the second case 20 is also possible.

Although the above-described embodiment has a configuration in which the upper drain channel 32 is inclined downward toward the two sides, and the lateral drain channels 33 are provided to both lateral surfaces, namely the left wall 16 and the right wall 17, of the first case 10, there is no limitation thereto. A configuration in which the upper drain channel is inclined downward from one side that is set to be higher than the other side toward the other side, and the lateral drain channel 33 is provided to only one of the left wall 16 and the right wall 17 of the first case 10 is also possible.

Although the above-described embodiment has a configuration in which the drain outlets 35 are formed at the portions where the first case 10 and the second case 20 are locked to each other, there is no limitation thereto. A drain outlet that connects the lateral drain channel 33 and the outside of the second case 20 may also be provided at a portion other than the portion where the first case 10 and the second case 20 are locked to each other.

The number and the arrangement of the drain outlets 35, and the numbers and the arrangements of the locking portions 14 and the locked portions 24 are not limited to those in the above-described embodiment.

Although the above-described embodiment has a configuration in which a single circuit board 2 is accommodated, as a circuit assembly, in the electrical junction box 1, a configuration in which the circuit assembly includes a plurality of circuit boards and the like is also possible. When a plurality of circuit boards and the like are included, all of the circuit boards and the like are not necessarily accommodated in the accommodating portion of the first case, and some of them may be held on the outside, upper side, and the like of the accommodating portion. When some circuit boards and the like are held on the outside of the accommodating portion, it is preferable to provide waterproof coating thereon.

1. An electrical junction box comprising:
a circuit assembly;
a first case that includes an upper wall and is provided with an accommodating portion for accommodating the circuit assembly; and
a second case that is locked to the first case and covers the accommodating portion,
wherein a reservoir portion with a recessed shape for storing water infiltrating through a boundary between the first case and the second case is provided on an upper side of the upper wall of the accommodating portion, and
the second case covers an upper side of the reservoir portion and is locked to the first case such that a distance of a gap between an upper edge of the reservoir portion and an inner surface of the second case is smaller than or equal to a predetermined distance.

2. The electrical junction box according to claim 1, wherein a plurality of the reservoir portions are lined up along an edge of the second case on the upper side of the upper wall of the first case.

3. The electrical junction box according to claim 1,
wherein the first case includes a left wall and a right wall that extend downward from two lateral edges of the upper wall,
an upper drain channel extending to a lateral drain channel formed on at least one of the left wall and the right wall is provided at a position adjacent to the reservoir portion on a side opposite to the edge of the second case on the upper side of the upper wall of the first case, and
a drain outlet is provided that connects the lateral drain channel and an outside of the second case in a state in which the second case is locked to the first case and through which water flowing on the lateral channel is drained outward from the second case.

4. The electrical junction box according to claim 3, wherein an inclined surface that is inclined downward toward the upper drain channel is formed at an upper edge of a lateral wall on the upper drain channel side of the reservoir portion.

5. The electrical junction box according to claim 2, wherein the first case includes a left wall and a right wall that extend downward from two lateral edges of the upper wall,
an upper drain channel extending to a lateral drain channel formed on at least one of the left wall and the right wall is provided at a position adjacent to the reservoir portion on a side opposite to the edge of the second case on the upper side of the upper wall of the first case, and
a drain outlet is provided that connects the lateral drain channel and an outside of the second case in a state in which the second case is locked to the first case and through which water flowing on the lateral channel is drained outward from the second case.
